(19) United States
(12) Patent Application Publication
(10) Pub. No.: US 2024/0254615 A1
(43) Pub. Date: Aug. 1, 2024

(54) CLADDING TUBES COATING APPARATUS

(71) Applicant: KOREA ATOMIC ENERGY RESEARCH INSTITUTE, Daejeon (KR)

(72) Inventors: Hyun Gil KIM, Daejeon (KR); Sung Eun KIM, Seoul (KR); Jongdae HONG, Daejeon (KR); HongRyoul OH, Daejeon (KR)

(21) Appl. No.: 18/408,870

(22) Filed: Jan. 10, 2024

(30) Foreign Application Priority Data
Jan. 31, 2023 (KR) 10-2023-0013236

(51) Int. Cl. C23C 14/14; C23C 14/32; C23C 14/50; C23C 14/54

(52) U.S. Cl. CPC C23C 14/14; C23C 14/325; C23C 14/505; C23C 14/542

(57) ABSTRACT

A cladding tube coating apparatus includes a chamber unit configured to create a zirconium alloy coating environment using arc ion plating, a rotating support portion provided in the chamber unit to accommodate a plurality of cladding tubes, which are coating objects, and a target portion provided in the chamber unit toward the plurality of cladding tubes accommodated in the rotation support portion and ionized as an oxidation-resistant material is melted and evaporated due to an arcing phenomenon, wherein the rotation support portion includes a plurality of rotary tables on which the plurality of cladding tubes are rotationally supported, supports the rotary tables so that a rotation speed of the plurality of cladding tubes is constant at a preset speed, and supports the rotary table to maintain a coating thickness uniformly in longitudinal and circumferential directions.

### CROSS-REFERENCE TO RELATED APPLICATION

This application claims priority to and the benefit of Korean Patent Application No. 10-2023-0013236 filed in the Korean Intellectual Property Office on Jan. 31, 2023, the entire contents of which are incorporated herein by reference.

### BACKGROUND OF THE INVENTION

### (a) Field of the Invention

The disclosure relates to a cladding tube coating apparatus.

### (b) Description of the Related Art

Accident tolerant fuel (ATF) cladding tubes have been researched and developed for the purpose of preventing hydrogen explosion by reducing the amount of hydrogen produced in a high-temperature water vapor environment in the event of a nuclear power plant accident. ATF cladding tubes should be developed by placing emphasis on meeting various performance requirements under extreme environments, including corrosion resistance, creep resistance, stability under irradiation deformation, and storage disposal-related characteristics of conventional cladding tubes and improving oxidation resistance. However, considering economic efficiency and rapid commercialization, ATF cladding tubes have been developed around the world by coating the surfaces of conventional zirconium (Zr) alloy cladding tubes with an oxidation-resistant material.

To this end, the Korea Atomic Energy Research Institute has studied a method of surface treatment by applying a 3D printing process to the surfaces of conventional zirconium alloy cladding tubes and a method of coating by applying arc ion plating (AIP) technology. The AIP method has been selected as a method of improving oxidation resistance by coating a Cr and CrAl alloy without damaging a base material of commercial zirconium alloy cladding tubes, and commercialization technology development is in progress.

However, the AIP process of laminating a coating layer on a zirconium alloy cladding tube has limitations in loading and coating a large amount of cladding tubes in AIP equipment. The cladding tube has dimensions of 9.5 cm in diameter, 0.57 cm in thickness, and 4 m in length. When coating cladding tubes in AIP equipment, there are methods of arranging the cladding tubes horizontally and vertically. In the horizontal arrangement method, due to a bending phenomenon of the cladding tubes due to their own weight, a jig becomes complicated to load a large amount of cladding tubes into AIP equipment and it is not easy to create conditions in which mutual interference does not occur. Accordingly, the Korea Atomic Energy Research Institute has been performed Cr and CrAl alloy coating since 2014 using a method of vertically arranging cladding tubes in AIP equipment. However, there are limitations in coating a large amount of cladding tubes at once during AIP coating.

As a related art document, Korean Application Publication No. 2020-0123656 discloses “Film forming device for nuclear fuel cladding tube.”

### SUMMARY OF THE INVENTION

The disclosure attempts to provide cladding tube coating apparatus capable of increasing coating efficiency by loading a large amount of cladding tubes into arc ion plating (AIP) equipment and to improving a coating rate per unit time, while reducing variations in coating thickness in longitudinal and circumferential directions of the cladding tubes.

Embodiments according to the disclosure may be used to achieve other tasks not specifically mentioned, in addition to the above tasks.

A cladding tube coating apparatus according to an exemplary embodiment includes: a chamber unit configured to create a zirconium alloy coating environment using arc ion plating, a rotating support portion provided in the chamber unit to accommodate a plurality of cladding tubes, which are coating objects, and a target portion provided in the chamber unit toward the plurality of cladding tubes accommodated in the rotation support portion and ionized as an oxidation-resistant material is melted and evaporated due to an arcing phenomenon, wherein the rotation support portion includes a plurality of rotary tables on which the plurality of cladding tubes are rotationally supported, supports the rotary tables so that a rotation speed of the plurality of cladding tubes is constant at a preset speed, and supports the rotary table to maintain a coating thickness uniformly in longitudinal and circumferential directions.

According to an embodiment, during a metal coating film deposition process using arc ion plating (AIP) equipment, a homogeneous coating layer may be formed, while charging a large amount of cladding tubes and increasing coating efficiency.

In addition, according to an embodiment, a coating rate per unit time may be adjusted, while maintaining a coating thickness uniformly in the longitudinal and circumferential directions of the cladding pipes.

In addition, according to an embodiment, an apparatus for coating a cladding tube for nuclear fuel economically and with excellent quality may be provided.

### BRIEF DESCRIPTION OF THE DRAWINGS

FIG. 1 is a diagram illustrating a cladding tube coating apparatus according to an embodiment.

FIG. 2 is a diagram illustrating a rotation support portion according to an embodiment.

FIG. 3 is a diagram illustrating a separated coupling structure of a cladding tube according to an embodiment.

FIG. 4 is a diagram illustrating the coating overlap region of a cladding tube according to an embodiment.

### DETAILED DESCRIPTION OF THE EMBODIMENTS

Hereinafter, exemplary embodiments of the disclosure will be described in detail with reference to the accompanying drawings to allow those skilled in the art to practice the disclosure. As those skilled in the art would realize, the described embodiments may be modified in various different ways, all without departing from the spirit or scope of the disclosure. In the drawings, portions irrelevant to the description are omitted to clearly describe the disclosure, and like reference numerals denote like elements throughout the specification. Also, detailed descriptions of a known art will be omitted.

Throughout the specification, unless explicitly described to the contrary, the word “comprise”, and variations, such as “comprises” or “comprising”, will be understood to imply the inclusion of stated elements but not the exclusion of any other elements.

Hereinafter, the cladding tube coating apparatus will be described in detail with reference to the drawings.

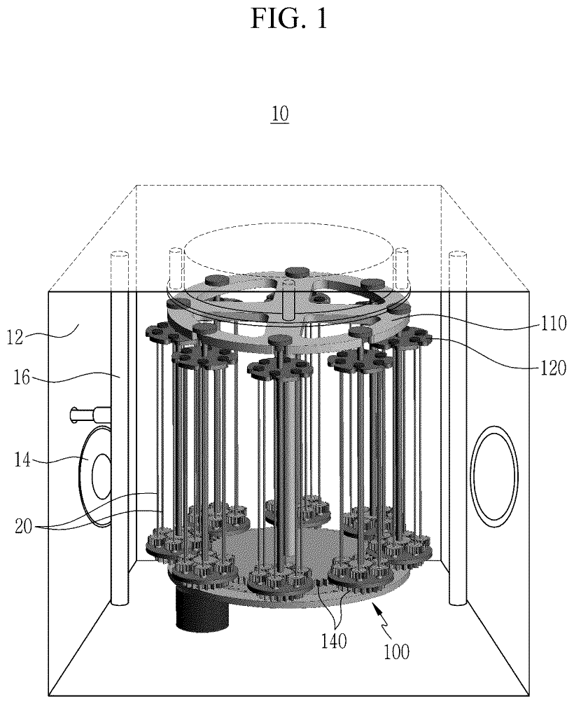

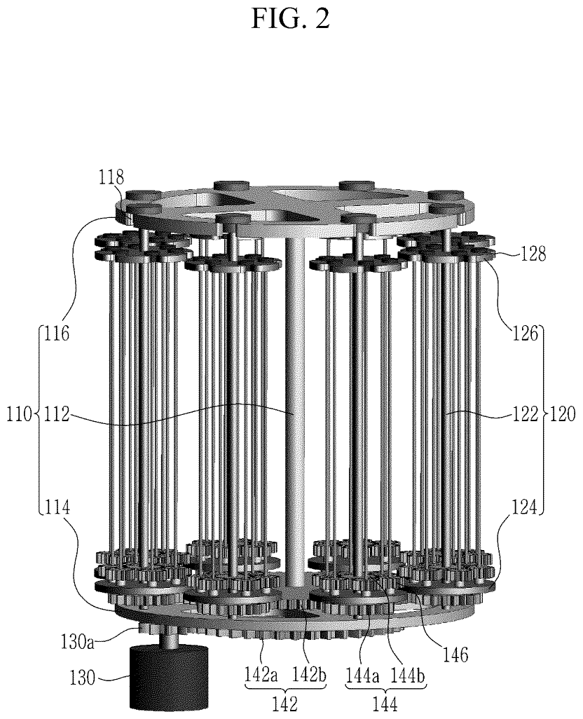

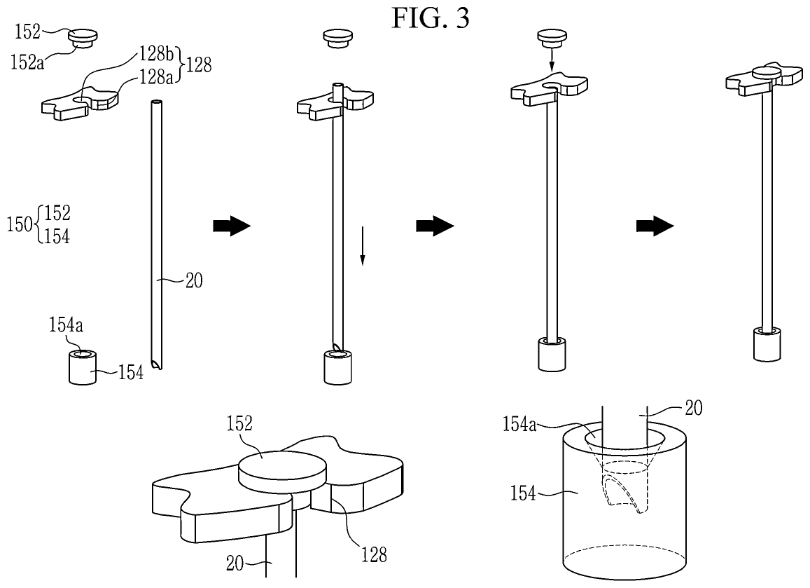

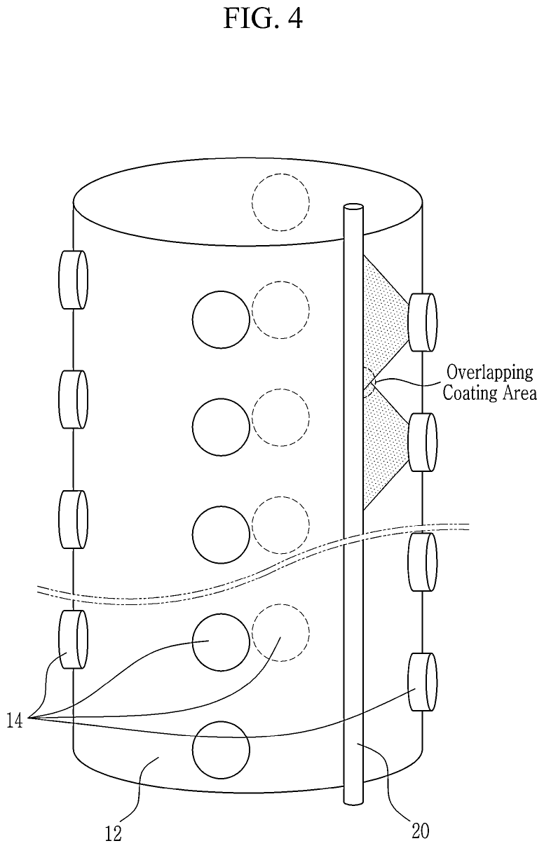

FIG. 1 is a diagram illustrating a cladding tube coating apparatus according to an embodiment, and FIG. 2 is a diagram illustrating a rotation support portion according to an embodiment. Also, FIG. 3 is a diagram illustrating a separated coupling structure of a cladding tube according to an embodiment, and FIG. 4 is a diagram illustrating a coating overlap region of a cladding tube according to an embodiment.

Referring to FIGS. 1 to 4, a cladding tube coating apparatus 10 according to an embodiment includes a chamber unit 12, a rotation support portion 100, and a target portion 14. The cladding tube coating apparatus 10 may load a large amount of cladding tubes 20 into arc ion plating (AIP) equipment and increase coating efficiency. In addition, according to an embodiment, a coating rate per unit time may increase, while variations in coating thickness are low in longitudinal and circumferential directions of the cladding tube 20.

The chamber unit 12 may create a zirconium alloy coating environment using arc ion plating. The chamber unit 12 may be formed as a vacuum chamber unit. Referring to FIG. 1, the interior of the chamber unit 12 may be provided with the target portion 14, a heater unit 16, the rotation support portion 100, and a cladding tube 20 which is a coating object. Within the chamber unit 12, a rotary table and the cladding tube 20 included in the rotating support portion 100 each rotate. A rotational movement of the cladding tube 20 may be maintained so that the entire surface of the cladding tube 20 may be coated at the same time as the rotary table moving toward or away from the target portion 14 rotates. Since the number of cladding tubes 20 that may be mounted on the rotating support portion 100 increases, mounting of a large number of cladding tubes 20 may be implemented.

The rotation support portion 100 may be provided in the chamber unit 12 and may accommodate a plurality of cladding tubes 20, which are coating objects. The rotation support portion 100 may include a plurality of rotary tables that rotate and support the plurality of cladding tubes 20. The rotation support portion 100 supports the plurality of cladding tubes 20 and the rotary table so that the rotation speed of the plurality of cladding tubes 20 is constant at a preset speed. In addition, the rotation support portion 100 supports the plurality of cladding tubes 20 and the rotary table to maintain the coating thickness uniformly in the longitudinal and circumferential directions of the plurality of cladding tubes 20.

The rotation support portion 100 may include a first rotary table 110 and a second rotary table 120.

The first rotary table 110 includes a lower portion formed in the shape of a disk of a preset first size. In addition, the first rotary table 110 may have a shape other than a disk shape, such as a polygonal plate shape. An upper portion of the first rotary table 110 is coupled and connected to a first central shaft 112 in a height direction to form a mounting space in the circumferential direction, and the first rotary table 110 may rotate according to transmission of external force.

The first rotary table 110 may include an 11th rotary plate 114 and a 12th rotary plate 116. The 11th rotary plate 114 may be provided at a lower portion of the first rotary table 110 and may support a lower portion of the first central shaft 112. The 12th rotary plate 116 may be provided at an upper portion of the first rotary table 110 and may be provided above the 11th rotary plate 114 to support the upper portion of the first central shaft 112. The 12th rotary plate 116 may be spaced apart at a preset interval in the circumferential direction and may include a shaft mounting recess 118 so that a corresponding shaft may be mounted thereon.

The second rotary table 120 includes a circular rotary plate that may easily install and detach the cladding tube 20 and stably maintain the mounted state of the cladding tube 20. In addition, the second rotary table 120 may have other shapes, such as a polygonal plate shape, in addition to the disk shape. A plurality of cladding tubes 20 may be mounted on the rotary plate. The second rotary table 120 may be provided in plurality, so that a greater number of cladding tubes 20 may be mounted on the plurality of second rotary tables 120, respectively. If necessary, the second rotary tables 120 may be expanded and arranged in a space of the rotating support portion 100. In this case, the space of the rotation support portion 100 may be expanded to fit an inner diameter of the chamber unit 12. Depending on the size of the second rotary table 120, the number of cladding tubes 20 that may be mounted on the second rotary table 120 may be limited. By forming the second rotary table 120 in a plate shape, a plurality of cladding tubes 20 may be mounted on the second rotary table 120. At least six or more cladding tubes 20 may be mounted on one second rotary table 120 in the circumferential direction. In addition, the second rotary table 120 may be provided in plurality, and may be formed in a structure that allows the second rotary tables 120 to be mounted within a range in which there is no interference between the second rotary tables 120 adjacent to each other.

The second rotary table 120 is provided in plurality in the circumferential direction of the first rotary table 110 and includes a lower portion of a preset second size. An upper portion of the second rotary table 120 is coupled and connected to a second central shaft 122 in the height direction to form a space for mounting a plurality of cladding tubes 20 and may rotate in conjunction with the rotation of the first rotary table 110. The first size of the first rotary table 110 may be larger than the second size of the second rotary table 120.

The second rotary plate 120 may include a 21st rotary plate 124 and a 22nd rotary plate 126. The 21st rotary plate 124 is provided at a lower portion of the second rotary table 120 and may support a lower portion of the second central shaft 122. The 22nd rotary plate 126 may be provided at an upper portion of the second rotary table 120 and may be provided above the 21st rotary plate 124 to support the upper portion of the second central shaft 122. The 22nd rotary plate 126 may be spaced apart at a preset interval in the circumferential direction and may include a cladding tube mounting recess 128 so that the corresponding cladding tube 20 may be installed and mounted in a separate coupling structure.

The cladding tube mounting recess 128 may include an inlet recess 128a and a seating recess (128b). The inlet recess 128a is located on a circumferential surface of the 22nd rotary plate 126 and has a shape of an opening into which the cladding tube 20 is inserted. The seating recess 128b may be located inside the 22nd rotary plate 126, may be in a position connected to the inlet recess 128a, and may support a state in which an outer diameter of the cladding tube 20 is inserted and seated.

The rod-shaped cladding tube 20 may be formed to be separated and coupled to the 22nd rotary plate 126 in a fitting structure.

The cladding tube 20 may be separately coupled to the cladding tube mounting recess 128 of the 22nd rotary plate 126. In addition, upper and lower portions of the cladding tube 20 may be coupled to separate fixing portions 150, while being mounted in the cladding tube mounting recess 128 of the 22nd rotary plate 126. The fixing portion 150 may be formed in a shape of a fixing cap that is separately coupled to the upper and lower portions of the cladding tube 20 with a fitting structure. The fixing portion 150 may include a first fixing cap 152 provided with a first fixing recess 152a into which the upper portion of the cladding tube 20 is inserted and a second fixing cap 154 provided with a second fixing recess 154a into which the lower portion of the cladding tube 20 is inserted. The first fixing recess 152a may be formed in a circular straight structure. The second fixing recess 154a may be formed in a structure inclined in a preset direction. The lower portion of the cladding tube 20 may be formed to be inclined to correspond to the inclined structure of the second fixing recess 154a. In this manner, the lower portion of the cladding tube 20 is formed in an inclined structure, and as it is inserted into the inclined second fixing recess 154a, self-rotation of the cladding tube 20 may be prevented. Since the upper portion of the cladding tube 20 and the inside of the first fixing recess 152a are formed in a circular structure, and the lower portion of the cladding tube 20 and the inside of the second fixing recess 154a are formed in an inclined structure, rotation of the cladding tube 20 may be prevented.

The second central shaft 122 coupled to the second rotary table 120 may be separately coupled to the shaft mounting recess 118 of the 12th rotary plate 116. Also, while the second central shaft 122 is mounted in the axis mounting recess 118 of the 12th rotary plate 116, upper and lower portions thereof may be coupled by separate fixing portions. The fixing portion may be formed in a shape of a fixing cap that is separately coupled to the upper and lower portions of the second central shaft 122 with a fitting structure. The fixing portion may include a first fixing cap provided with a first fixing recess into which the upper portion of the second central shaft 122 is inserted and a second fixing cap provided with a second fixing recess into which the lower portion of the second central shaft 122 is inserted. The first fixing recess may be formed in a circular straight structure. The second fixing recess may be formed in a structure inclined in a preset direction. The lower portion of the second central shaft 122 may be formed to be inclined to correspond to the inclined structure of the second fixing recess. In this manner, since the lower portion of the second central shaft 122 is formed in an inclined structure and is inserted into the inclined second fixing recess, self-rotation of the second central shaft 122 may be prevented. Since the upper portion of the second central shaft 122 and the inside of the first fixing recess are formed in a circular structure and the lower portion of the second central shaft 122 and the inside of the second fixing recess are formed in an inclined structure, rotation of the second central shaft 122 may be prevented.

The target portion 14 may be provided in the chamber unit 12 toward the plurality of cladding tubes 20 accommodated in the rotation support portion 100 and may be ionized as an oxidation-resistant material is melted and evaporated by an arcing phenomenon. Here, the oxidation-resistant material may include Cr or a Cr alloy. The Cr alloy may include a Cr-based alloy including Cr—Al. The target portion 14 may be provided in plurality in the height direction of the chamber unit 12. For example, a plurality of target portions 14 may be provided in the height direction on the front, rear, left, and right sides of the chamber unit 12, respectively. In addition, within the chamber unit 12, the target portions 14 may be arranged in plurality based on the circumferential direction of the rotation support portion 100. For example, within the chamber unit 12, the target portion 14 may be arranged in four rows at 90 degrees each based on the circumferential direction of the rotation support portion 100. By arranging one or two rows of target portions in 4 rows at 90 degrees in the circumferential direction, a coating rate may increase twice compared to the two-row arrangement. In addition, the target portions 14 may have a zigzag, odd (0, 180 degrees) and even (90, 270 degrees) arrangement structure from a bottom surface to have different heights in the circumferential direction. As the plurality of target portions 14 are arranged in the circumferential direction, coating efficiency per unit time may be improved. In addition, by arranging the target portions 14 at different heights from the bottom surface (zigzag, odd-even), the variations in thickness thereof in the longitudinal direction may be minimized.

Since there is a region coated on the cladding tube 20 in each target portion 14, the target portions 14 may be arranged so that an overlapping region of a coating material generated or radiated from the upper and lower target portions 14 may be 10% or more. The target portions 14 may be arranged so that a distance between adjacent target portions 14 overlap by 10% or more in the region coated on the cladding tube 20. Since there is a region coated on the cladding tube 20 in each target portion 14 and the target portions 14 are arranged so that the overlapping region of the coating material generated from the upper and lower target portions 14 is 10% or more, the coating rate per unit time may be increased while the coating layer having a uniform thickness in the longitudinal direction on the cladding tube 20 having a length of 4 m is obtained.

The rotation support portion 100 may further include a driving unit 130 and a power transmission unit 140.

The driving unit 130 is provided on one side of the first rotary table 110 and may generate a rotational driving force transmitted to the first rotary table 110. The driving unit 130 may include a motor capable of controlling rotation speed. The drive shaft of the driving unit 130 may be provided with a drive gear 130a that transmits power to the power transmission unit 140. By controlling the rotation speed of the driving unit 130, a rotation speed of the cladding tube 20 may be controlled. For example, the rotation speed of the driving unit 130 and that of the cladding tube 20 may be controlled to match. Also, by adjusting a gear ratio of the power transmission unit 140, which transmits a rotational force generated by the driving unit 130 to the rotary table, the rotation speed of the plurality of cladding tubes 20 provided in the circumferential direction of the rotary table may be maintained to be constant and the cladding tube 20 may continuously rotate. By adjusting each gear ratio provided between the power transmission unit 140 connected to the driving unit 130 and the cladding tube 20 connected to the power transmission unit 140, the rotation speed of the driving unit 130 and the rotation speed of the cladding tube 20 may be controlled to be 1:1. If the rotation speed of the cladding tube 20 is fast, coating efficiency decreases. Therefore, by adjusting the rotation speed of the cladding tube 20 by adjusting the rotation speed of the driving unit 130, the coating efficiency of the cladding tube 20 may be increased. For this reason, uniform coating of the cladding tube 20 may be achieved.

The power transmission unit 140 may be provided between the driving unit 130 and the first rotary table 110 and between the first rotary table 110 and the second rotary table 120 to transmit rotational driving force of the driving unit 130. The power transmission unit 140 may include a first gear portion 142, a second gear portion 144, and a third gear portion 146. Since the coating accumulates in a vacuum state, the gear portion may be used preferentially to transmit the driving force of the rotary table. Also, since the rotation speed of the cladding tube 20 should be constant at each position, a reduction gear may be used to control the rotation speed due to an increase in a rotation diameter.

The first gear portion 142 may have a first gear ratio that reduces the rotation speed of the driving unit 130 and may be connected to the lower portion of the first rotary table 110 by shaft coupling. The first gear portion 142 may include an 11th gear portion 142a and a 12th gear portion 142b. The 11th gear portion 142a may be provided on a lower side below the first rotary table 110 and directly connected to the driving unit 130. The 12th gear portion 142b may have the same shape as that of the 11th gear portion 142a, may be provided above the 11th gear portion 142a at a lower portion of the first rotary table 110, may be concentrically connected to the 11th gear portion 142a, and may be directly connected to the second gear portion 144.

The second gear portion 144 may have a second gear ratio that increases the rotation speed of the first gear portion 142 and may be connected to the second rotary table 120 through a shaft coupling. The second gear portion 144 may include a 21st gear portion 144a and a 22nd gear portion 144b. The 21st gear portion 144a may be provided on a lower side below the second rotary table 120 and directly connected to the 12th gear portion 142b. The 22nd gear portion 144b may have a gear ratio that reduces the rotation speed of the 21st gear portion 144a, may be provided above the 21st gear portion 144a at an upper portion of the second rotary table 120, and may be concentrically connected to the 21st gear portion 144a, and may be directly connected to the third gear portion 146.

The third gear portion 146 may have a third gear ratio that reduces the rotation speed of the second gear portion 144 and may be connected to the periphery of the second gear portion 144 on the second rotary table 120 by axial coupling. The third gear portion 146 may be provided at a lower portion of the corresponding cladding tube 20.

As described above, according to the rotation of the driving unit 130, the rotation of the cladding tube 20 may be connected in a relationship of gradual deceleration and acceleration. First rotation of the driving unit 130, second rotation the first rotary table 110 connected to the driving unit 130, third rotation of the second rotary table 120 connected to the first rotary table 110, and then, fourth rotation of the cladding tube 20 mounted on the second rotary table 120 may be performed sequentially.

Here, the cladding tube 20 should maintain electrical contact with the rotary table, the gear portion, and a portion in which the cladding tube 20 is mounted so that a bias voltage is applied during coating. In addition, the rotary table may be formed so that the cladding tube 20 is loaded from the outside and mounted on a mounting portion at once in a fitting manner. The cladding tube 20 should be rotated to be uniformly coated in the circumferential direction. The cladding tube 20 may be rotated to constantly face the target portion 14 in the circumferential direction, so that a coating of uniform thickness may be implemented. The driving unit 130 and the power transmission unit 140 should maintain the gea portion so that the cladding tube 20 is constant in rotation speed and continuously rotate, and rotation speeds thereof should be controlled. By providing the gear portion that controls the rotation speed of the cladding tube 20 and adjusting each gear ratio, the rotation speed of the cladding tube 20 may be maintained to be continuously constant.

When the cladding tube 20 is mounted away from the first central shaft 112, which is the central shaft of rotation of the first rotary table 110, the rotation speed of the first rotary table 110 at the position of the cladding tube 20 may relatively increase, and thus, coating of the cladding tube 20 may not be smoothly performed. When a diameter of the rotary table 110 increases, the amount of rotation increases relative to the rotation speed provided by the driving unit 130, so coating of the cladding tube 20 cannot be performed smoothly. As a result, time for ions to attach may decrease, so a coating film may become thinner and coating efficiency may decrease.

To solve this problem, the driving unit 130 and the first rotary table 110 may be connected via the first gear portion 142. In order to reduce the rotation speed due to an increase in a rotation radius away from the driving unit 130, the first rotary table 110 is connected to the first gear portion 142 having the first gear ratio. At this time, a method of increasing a reduction ratio of the driving unit 130 and the first gear portion 142 when the rotation radius of the first rotary table 110 increases may be applied. The first rotary table 110 connected to the driving unit 130 that is rotated first is decelerated via the first gear portion 142 and rotated secondly.

The first rotary table 110 and the second rotary table 120 on which a large number of cladding tubes 20 are mounted are connected via the second gear portion 144. In order to increase the rotation speed of the second rotary table 120 compared to the rotation speed of the first rotary table 110, the first rotary table 110 and the second rotary table 120 are connected by the second gear portion 144 having the second gear ratio.

At this time, a method of reducing a speed increase ratio of the first gear portion 142 and the second gear portion 144 when the radius of the second rotary table 120 increases may be applied. The second rotary table 120 connected to the first rotary table 110, which is rotated secondly, is sped up via the second gear portion 144 and rotated thirdly.

The second rotary table 120 and the cladding tube 20 are connected via the third gear portion 146. In order to increase the rotation speed of the cladding tube 20 compared to the rotation speed of the second rotary table 120, the second rotary table 120 and the cladding tube 20 are connected via the third gear portion 146 having the third gear ratio.

At this time, a method of reducing a speed increase ratio of the second gear portion 144 and the third gear portion 146 when a rotation radius of the cladding tube 20 on the second rotary table 120 increases may be applied. The cladding tube 20 connected to the second rotary table 120, which is rotated third time, is sped up via the third gear portion 146 and rotated fourth time.

In order to match the rotation speed that varies depending on the mounting position of the cladding tube 20, such as when the second rotary table 120 on which the cladding tube 20 is mounted is located in the middle of the first rotary table 110, which is a main support table, a corresponding reduction gear may be changed and applied. In addition, the second rotary table 120 and the cladding tube 20 may be implemented to rotate separately. For example, a rotation movement of the cladding tube 20 may be implemented so that the entire surface of the cladding tube 20 is uniformly coated at the same time as the rotation of the second rotary table 120 that approaches and moves away from the cladding tube 20 based on the target portion 14.

As described above, the cladding tube coating apparatus 10 according to an embodiment may load a large amount of cladding tubes 20 during a metal coating film deposition process using arc ion plating (AIP) equipment and obtain a homogeneous coating layer, while increasing coating efficiency. In an embodiment, a large amount of cladding tubes 20 may be loaded into arc ion plating (AIP) equipment and coating efficiency may be increased. In addition, during the metal coating film deposition process using the AIP equipment, a large amount of cladding tubes 20 may be easily loaded and a homogeneous coating layer may be provided, while increasing the coating efficiency of the plurality of loaded cladding tubes 20. The AIP method is a suitable method for coating accident-tolerant fuel (ATF) cladding tube with oxidation-resistant materials, but if mass production is difficult, manufacturing costs may increase and price competitiveness cannot be secured. Therefore, in order to increase the coating efficiency of the AIP equipment, in the cladding tube coating apparatus 10 according to an embodiment, the zirconium alloy cladding tube may be coated with an oxidation-resistant material through an AIP process within a limited space of the chamber unit 12. In this case, by forming a rotation support portion 100 that increases the load number of cladding tubes 20 and controlling the rotation of the cladding tubes 20, a coating rate per unit time may be adjusted, while maintaining the coating thickness uniformly in the longitudinal and circumferential directions of the cladding tubes 20.

In the process of depositing the oxidation-resistant materials for ATF cladding tube using the AIP method, it may be difficult to secure economic feasibility due to the increase in coating costs unless coating efficiency is increased. Accordingly, in an embodiment, in the development of a coating technology using the AIP technology of zirconium alloy, not only the uniformity of the coating layer may be improved but also the coating rate may be increased by increasing the amount of the cladding tubes 20. The ATF is a core technology that should be applied to all operating nuclear power plants in the future according to the EU taxonomy's standard that ATF should be applied to nuclear power plants operating after 2025. Therefore, the application of the ATF cladding tubes to operating nuclear power plants is inevitable, and an embodiment is a core technology that may manufacture ATF cladding tubes economically and with excellent quality, which is anticipated to not only improve the safety of operating nuclear power plants, but also have a significant economic effect from possessing the technology.

The embodiments of the disclosure have been described in detail, but the scope of the disclosure is not limited thereto and various variants and modifications by a person skilled in the art using a basic concept of the disclosure defined in claims also belong to the scope of the disclosure.

What is claimed is:

1. A cladding tube coating apparatus comprising:
a chamber unit configured to create a zirconium alloy coating environment using arc ion plating;
a rotating support portion provided in the chamber unit to accommodate a plurality of cladding tubes, which are coating objects; and
a target portion provided in the chamber unit toward the plurality of cladding tubes accommodated in the rotation support portion and ionized as an oxidation-resistant material is melted and evaporated due to an arcing phenomenon.
wherein the rotation support portion includes
a plurality of rotary tables on which the plurality of cladding tubes are rotationally supported, supports the rotary tables so that a rotation speed of the plurality of cladding tubes is constant at a preset speed, and supports the rotary table to maintain a coating thickness uniformly in longitudinal and circumferential directions.

2. The cladding tube coating apparatus of claim 1, wherein:
the rotation support portion includes:
a first rotary table including a lower portion of a preset first size and an upper portion coupled and connected to a first central shaft in a height direction, forming a mounting space in the circumferential direction, and rotating according to transmission of external force, and
a second rotary table provided in plurality in the circumferential direction of the first rotary table, including a lower portion of a preset second size, including an upper portion coupled and connected to a second central shaft in the height direction, forming a plurality of cladding tube mounting spaces, and rotating in conjunction with rotation of the first rotary table.

3. The cladding tube coating apparatus of claim 2, wherein:
the first rotary table includes:
an 11th rotary plate provided on a lower side to support a lower portion of the first central shaft, and
a 12th rotary plate provided on an upper side of the 11th rotary plate to support an upper portion of the first central shaft.

4. The cladding tube coating apparatus of claim 3, wherein:
the 12th rotary plate is spaced apart at a preset interval in the circumferential direction and includes a shaft mounting recess so that a corresponding shaft is mounted thereon.

5. The cladding tube coating apparatus of claim 2, wherein:
the rotation support portion further includes
a driving unit provided on one side of the first rotary table and generating a rotational driving force transmitted to the first rotary table.

6. The cladding tube coating apparatus of claim 5, wherein:
the rotation support portion further includes:
a power transmission unit provided between the driving unit and the first rotary table and between the first rotary table and the second rotary table to transmit the rotational driving force of the driving unit.

7. The cladding tube coating apparatus of claim 6, wherein:
the power transmission unit includes:
a first gear portion having a first gear ratio that reduces a rotation speed of the driving unit and connected to a lower portion of the first rotary table by shaft coupling,
a second gear portion having a second gear ratio that increases a rotation speed of the first gear portion and connected to the second rotary table by shaft coupling, and
a third gear portion having a third gear ratio that reduces a rotation speed of the second gear portion and connected to a periphery of the second gear portion on the second rotary table by shaft coupling.

8. The cladding tube coating apparatus of claim 7, wherein:
the first gear portion includes:
an 11th gear portion provided on a lower side below the first rotary table and directly connected to the driving unit, and
a 12th gear portion having a same shape as the 11th gear portion, provided on an upper side of the 11th gear portion at a lower portion of the first rotary table, concentrically connected to the 11th gear portion, and directly connected to the second gear portion.

9. The cladding tube coating apparatus of claim 8, wherein:
the second gear portion includes:
a 21st gear portion provided on a lower side at a lower portion of the second rotary table and directly connected to the 12th gear portion, and
a 22nd gear portion having a gear ratio that reduces a rotation speed of the 21st gear portion, provided on an upper side of the 21st gear portion at an upper portion of the second rotary table, concentrically connected to the 21st gear portion, and directly connected to the third gear portion.

10. The cladding tube coating apparatus of claim 9, wherein:
the third gear portion is provided at a lower portion of a corresponding cladding pipe.

11. The cladding tube coating apparatus of claim 2, wherein:
the second rotary table includes:
a 21st rotary plate provided on a lower side to support a lower portion of the second central shaft, and
a 22nd rotary plate provided on an upper side of the 21st rotary plate to support an upper portion of the second central shaft.

12. The cladding tube coating apparatus of claim 11, wherein:
the 22nd rotary plate is spaced apart at a preset interval in the circumferential direction and is provided with a cladding tube mounting recess so that a corresponding cladding tube is mounted in a separate coupling structure.

13. The cladding tube coating apparatus of claim 12, wherein:
the cladding tube mounting recess includes:
an inlet recess provided in a shape of an opening through which the cladding tube is inserted on a circumferential surface of the 22nd rotary plate, and
a seating recess provided at a position connected to the inlet recess on an inside of the 22nd rotary plate and supporting a state in which an outer diameter of the cladding tube is inserted and seated.

14. The cladding tube coating apparatus of claim 1, wherein:
the target portion is provided in plurality in a height direction of the chamber unit.

15. The cladding tube coating apparatus of claim 1, wherein:
the target portion is disposed in plurality within the chamber unit based on the circumferential direction of the rotation support portion.

16. The cladding tube coating apparatus of claim 15, wherein:
the plurality of target portions are arranged in a zigzag arrangement from a bottom surface so that the target portions have different heights based on the circumferential direction of the rotation support portion.
